(19) United States
(12) Patent Application Publication
(10) Pub. No.: US 2004/0112671 A1
(43) Pub. Date: Jun. 17, 2004

(54) Loudspeaker unit and assembly

(75) Inventor: Stephen Halsall, Tonbridge Wells (GB)

Correspondence Address: MYERS DAWES ANDRAS & SHERMAN, 11th Floor, 19900 MacArthur Blvd., Irvine, CA, 92612, US

(73) Assignee: KH Technology Corporation

(21) Appl. No.: 10/641,615

(22) Filed: Aug. 15, 2003

(30) Foreign Application Priority Data
Aug. 17, 2002 (GB) 0219244.1

(51) Int. Cl. H05K 5/00

(52) U.S. Cl. 181/156; 181/144

(57) ABSTRACT

A loudspeaker unit comprises, in combination, a pistonic loudspeaker and a resonant panel loudspeaker arranged such that the resonant panel is movable, for example by rotation, with respect to the pistonic loudspeaker. The resonant panel may be movable with respect to the pistonic loudspeaker between a first position in which the resonant panel covers the pistonic loudspeaker, and a second position in which pistonic loudspeaker is uncovered from the resonant panel. The resonant panel may be movable by means of a motor, for example by remote control. A loudspeaker assembly comprising a resonant panel loudspeaker, a support to which the resonant panel is attached, and a motor by which the resonant panel is movable with respect to the support, is also disclosed. The assembly may form part of the unit. The assembly or unit may be attached to a wall or other boundary, for example in a recess.

### FIELD OF THE INVENTION

The present invention relates to loudspeaker systems, particularly (although not exclusively) for use in “home cinema” applications.

### BACKGROUND OF THE INVENTION

A crucial aspect of home cinema systems is the nature and quality of the sound reproduction. An important feature of good home cinema sound reproduction is so-called “surround sound”, i.e. the illusion that the reproduced sound is emanating from all around the listener rather than from specific discrete sources (i.e. the surround sound loudspeakers). Conventionally, surround sound loudspeakers generally comprise two pistonic diaphragm drivers operating out of phase in order to produce a “figure-of-eight” dipole acoustic radiation directivity characteristic (the drivers may be in phase at base frequencies, or there may be a separate low frequency driver in the enclosure). However, such conventional pistonic surround sound loudspeakers suffer from the disadvantages that they tend to be expensive, and generally do not produce an entirely convincing ambient sound profile for the listener.

International patent application WO 99/62294 discloses a method of operating a resonant panel-form loudspeaker system, comprising arranging the loudspeaker panel near to a boundary so as to be acoustically linked to the boundary and with the plane of the loudspeaker panel at an angle (for example substantially normal) to the boundary. Such a loudspeaker system lacks a ‘pistonic’ loudspeaker and thus will not be capable of reproducing bass frequencies. A pistonic loudspeaker allows use of a panel which is small and cannot reproduce low mid-range frequencies. A pistonic loudspeaker is better able to produce high SPL at low frequencies.

### BRIEF SUMMARY OF THE INVENTION

The present invention seeks to provide a new loudspeaker system which is particularly suitable for creating surround sound reproduction, for example for home cinema applications. However, the invention is not limited to home cinema applications, or to surround sound in general, although such applications will be particularly suited to the invention.

Accordingly, a first aspect of the invention provides a loudspeaker unit comprising, in combination, a pistonic loudspeaker and a resonant panel loudspeaker arranged such that the resonant panel is movable with respect to the pistonic loudspeaker.

Preferably the resonant panel is rotatable with respect to the pistonic loudspeaker (i.e., a loudspeaker in which a diaphragm moves in a piston-like motion as a generally rigid whole for at least part of its operating frequency range).

Advantageously, the resonant panel may be movable with respect to the pistonic loudspeaker between a first position in which the resonant panel at least partially covers the pistonic loudspeaker, and a second position in which pistonic loudspeaker is substantially uncovered from the resonant panel. Preferably, in the first position the resonant panel substantially entirely covers the pistonic loudspeaker. When the resonant panel is in its second position the pistonic loudspeaker preferably is substantially entirely uncovered from the resonant panel.

The covering and uncovering of the pistonic loudspeaker by the resonant panel loudspeaker has the advantage (for example) of overcoming potential styling problems. When the resonant panel loudspeaker is in its first (“parked”) position and covers the pistonic loudspeaker, the resonant panel tends to minimise the visual impact of both loudspeakers (i.e. when they are not in use). The “parked” resonant panel also provides a degree of protection to the pistonic loudspeaker.

The covering or uncovering of the pistonic loudspeaker preferably comprises covering or uncovering of a pistonically driven diaphragm of the pistonic loudspeaker. When the resonant panel is in its second position, the panel preferably is oriented substantially parallel to an axis along which the diaphragm of the pistonic loudspeaker is pistonically driven.

At least in use, the unit preferably is attached to, mounted with respect to (or otherwise arranged with respect to) a wall or other acoustic boundary. The unit may for example, be attached to a wall or other boundary such that at least the pistonic loudspeaker is located in a recess in the wall (or other boundary). The resonant panel loudspeaker therefore preferably is acoustically linked to the boundary, at least in the sense that the boundary directly modifies the acoustic radiation emitted from the resonant panel. Preferably the attachment, mounting or arrangement is such that the pistonic loudspeaker is oriented with its pistonic axis generally (and preferably substantially) perpendicular to the boundary. Additionally or alternatively, the second position of the resonant panel preferably is generally (and more preferably substantially) perpendicular to the boundary.

It is particularly preferred for the first position of the resonant panel loudspeaker to be a non-operational position, and the second position of the resonant panel loudspeaker to be an operational position in which the resonant panel loudspeaker is able to emit acoustic radiation. Preferably the resonant panel is arranged to rotate between the first and second positions. Advantageously, therefore, the resonant panel preferably may be operated in substantially any orientation between the first and second positions (and preferably also in any of a range of positions beyond the second position from the first position).

Advantageously, the loudspeaker unit may further comprise a support to which the resonant panel is movably (preferably rotatably) attached.

The loudspeaker unit preferably further comprises a motor, by means of which the resonant panel is movable (preferably rotatable) with respect to the pistonic loudspeaker.

A second aspect of the invention provides a loudspeaker assembly comprising a resonant panel loudspeaker, a support to which the resonant panel is attached, and a motor by which the resonant panel is movable (preferably rotatable) with respect to the support.

The loudspeaker unit according to the first aspect of the invention preferably includes the assembly according to the second aspect of the invention (the resonant panel loudspeaker, the motor and the support of the assembly comprising those of the unit as aforesaid).

A third aspect of the invention provides a method of operating a loudspeaker unit according to the first aspect of the invention, or a loudspeaker assembly according to the second aspect of the invention, comprising moving the resonant panel loudspeaker between a non-operational first position and an operational second position in which the resonant panel loudspeaker is able to emit acoustic radiation.

By orientating the panel of the resonant panel loudspeaker so that it is non-parallel to a boundary such as wall, the panel loudspeaker normally produces a generally “figure-of-eight” acoustic radiation pattern by emitting acoustic radiation from both opposite major surfaces of the panel, with the “null” of the radiation pattern coincident with the panel itself. Consequently, the use of a resonant panel loudspeaker in this orientation produces the type of acoustic radiation pattern generally required of surround sound. Additionally, resonant panel loudspeakers tend to produce diffuse acoustic radiation, which is ideal for surround sound. These two characteristics in combination mean that the invention generally provides an extremely effective surround sound loudspeaker system. A further advantage is that operating the resonant panel loudspeaker in a non-parallel orientation with respect to a wall or other boundary generally increases the radiation efficiency of the panel.

Other preferred and optional features of the invention are described below.

### BRIEF DESCRIPTION OF THE DRAWINGS

FIG. 1 shows an example schematic plan view of a preferred embodiment of a loudspeaker unit 1 which incorporates a loudspeaker assembly, according to the present invention.

### DETAILED DESCRIPTION OF THE INVENTION

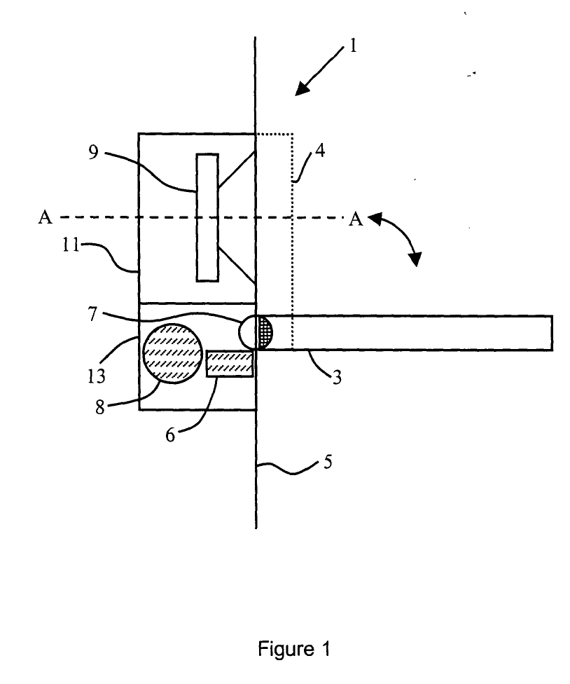

An embodiment of the invention will now be described, by way of example, with reference to the accompanying FIG. 1.

FIG. 1 is a schematic plan view of a preferred embodiment of a loudspeaker unit 1 according to the invention (which incorporates a loudspeaker assembly according to the invention).

The example loudspeaker unit 1 comprises, in combination, a pistonic loudspeaker 9 and a resonant panel loudspeaker 3 arranged such that the resonant panel 3 is movable with respect to the pistonic loudspeaker 9. By “pistonic loudspeaker” in this specification is meant a loudspeaker in which a diaphragm moves in a piston-like motion as a generally rigid whole for at least part of its operating frequency range (for example up to approximately 700 Hz).

Preferably the resonant panel 3 is rotatable with respect to the pistonic loudspeaker 9. As such, the resonant panel 3 is movable with respect to the pistonic loudspeaker 9 between a first position (a indicated by a dashed outline of the panel and reference numeral 4), in which the resonant panel 3 at least partially covers the pistonic loudspeaker 9, and a second position (as indicated by the panel as drawn in solid outline and indicated by reference numeral 3), in which pistonic loudspeaker 9 is substantially uncovered from the resonant panel 3. Preferably, in the first position the resonant panel 3 substantially entirely covers the pistonic loudspeaker 9. When the resonant panel 3 is in its second position the pistonic loudspeaker 9 preferably is substantially entirely uncovered from the resonant panel 3.

The covering and uncovering of the pistonic loudspeaker 9 by the resonant panel loudspeaker 3 has the advantage, for example, of overcoming potential styling problems. When the resonant panel loudspeaker 3 is in its first (“parked”) position and covers the pistonic loudspeaker 9, the resonant panel 3 tends to minimise the visual impact of both loudspeakers 3, 9 (i.e., when they are not in use). The “parked” resonant panel 3 also provides a degree of protection to the pistonic loudspeaker 9 from impact and the ambient.

The covering or uncovering of the pistonic loudspeaker 9 preferably comprises covering or uncovering of a pistonically driven diaphragm 10 of the pistonic loudspeaker 9. When the resonant panel 3 is in its second position, the panel 3 preferably is oriented substantially parallel to an axis along which the diaphragm 10 of the pistonic loudspeaker 9 is pistonically driven.

It is particularly preferred for the first position of the resonant panel loudspeaker 3 to be a non-operational position, and the second position of the resonant panel loudspeaker 3 to be an operational position in which the resonant panel loudspeaker 3 is able to emit acoustic radiation. Preferably the resonant panel 3 is arranged to rotate between the first and second positions. Advantageously, therefore, the resonant panel 3 preferably may be operated in substantially any orientation between the first and second positions (and preferably also in any of a range of positions beyond the second position from the first position).

At least in use, the loudspeaker unit 1 is preferably attached to, mounted with respect to (or otherwise arranged with respect to) a wall or other acoustic boundary. The unit 1 may for example, be attached to a wall or other boundary such that at least the pistonic loudspeaker 9 is located in a recess in the wall (or other boundary). The resonant panel loudspeaker 3 therefore preferably is acoustically linked to the boundary, at least in the sense that the boundary directly modifies the acoustic radiation emitted from the resonant panel 3. Preferably the attachment, mounting or arrangement is such that the pistonic loudspeaker 9 is oriented with its pistonic axis generally (and preferably substantially) perpendicular to the boundary. Additionally or alternatively, the second position of the resonant panel 3 preferably is generally (and more preferably substantially) perpendicular to the boundary.

As such, in the example described herein, the resonant panel loudspeaker 3 is attached by means of a support 7 to a wall 5. The support 7 includes mechanical gearing and the like (e.g. a cam) by which an electric motor 8 is able to rotate the resonant panel 3 (as indicated by the arrow). The electric motor 8 may be controlled by remote control, and a remote control circuit forms part of the unit and is indicated by reference numeral 6.

The resonant panel 3 is rotated by the electric motor 8 between a first, non-operational position as indicated by a dashed outline of the panel and reference numeral 4, and a second, operational position as indicated by the panel as drawn in solid outline and indicated by reference numeral 3. In the second, operational position the resonant panel 3 is substantially perpendicular to the wall 5, and in the first, non-operational position the panel 3 is substantially parallel to the wall 5. In the first position, the panel 3 preferably is substantially flush with the wall 5 and covers a pistonic loudspeaker 9 which also forms part of the loudspeaker unit 1.

The pistonic loudspeaker 9 is mounted in a recess in the wall 5 and is oriented such that its pistonic axis (shown as a dashed line A-A) is substantially perpendicular to the wall and consequently sound emitted from it is a hemispherical wave. The pistonic loudspeaker 9 preferably is a low frequency loudspeaker (e.g. a bass speaker, or “woofer”); preferably the pistonic loudspeaker 9 comprises a moving coil driven cone diaphragm loudspeaker.

The loudspeaker unit 1 further includes an enclosure 11 for the pistonic loudspeaker 9. Preferably the enclosure 11 comprises part of a housing for the entire loudspeaker unit 1. The unit 1 is preferably installed in a recess in the wall 5 (or other boundary) as shown in FIG. 1, but it may be merely attached to a boundary or located near to a boundary, for example.

Preferably, the resonant panel loudspeaker 3 comprises a panel which is arranged to vibrate by means of one or more exciters (i.e. the driving elements of the loudspeaker, not shown). Resonant panel loudspeakers are often termed “distributed-mode” loudspeakers (DMLs) because they generally function by exciting a plurality of vibrational modes distributed throughout the panel (the panel generally operating wholly in resonance).

Therefore, preferably the panel loudspeaker 3 comprises a resonant panel and one or more exciters for exciting the panel. The exciter(s) may generally comprise any type of transducer, for example electromagnetic (e.g. moving coil), piezoelectric, or electrostatic. The panel itself may be formed from any of a wide variety of materials, for example polymeric materials and/or glass fibre materials and/or carbon fibre materials and/or cardboard (or the like). The panel may comprise a single sheet of material, a plurality of layers (or other composite construction) and/or may include a core, for example of honeycomb or foam construction.

The panel is preferably substantially planar (i.e. a thin and flat panel). This has the advantage that the acoustic radiation patterns which emanate from each major surface of the panel may be substantially the same as each other (thereby, for example, enhancing the diffuse surround sound nature of the sound reproduction). However, the panel need not be planar, but may, for example, be curved in one or two dimensions.

As mentioned above, in operation (in the second position), the panel of the resonant panel loudspeaker 3 preferably is arranged such that the panel is generally perpendicular to the wall 5 or other acoustic boundary. By “generally perpendicular” is meant deviating from the perpendicular by, for example, no more than about 30 degrees, preferably no more than about 20 degrees, and especially no more than about 10 degrees. Most preferably the panel of the loudspeaker 9 is substantially perpendicular to the wall 5 or other boundary during operation of the loudspeaker.

The pistonic loudspeaker 9 may, for example, comprise a moving coil diaphragm loudspeaker having said a cone diaphragm 10. Preferably the pistonic loudspeaker 9 is a low frequency loudspeaker (e.g. a bass speaker or “woofer”).

As aforementioned, the pistonic loudspeaker 9 may be mounted in or on the wall 5 or other boundary. In especially preferred embodiments, the resonant panel loudspeaker 3 is movable between substantially parallel (first) and substantially non-parallel (second) orientations with respect to the wall 5 (or other boundary). When in its parallel orientation (i.e. its first position) the resonant panel loudspeaker 3 may cover (at least partially) the pistonic loudspeaker 9. Orientating the resonant panel loudspeaker 3 for use (to its second position) may therefore also expose the further loudspeaker 9 for use.

By orientating the resonant panel loudspeaker 3 so that it is non-parallel to a wall 5 (or other boundary) the panel loudspeaker 9 normally produces a generally “figure-of-eight” acoustic radiation pattern by emitting acoustic radiation from both opposite major surfaces of the panel, with the “null” of the radiation pattern coincident with the panel itself. Consequently, the use of a resonant panel loudspeaker 3 in this orientation produces the type of acoustic radiation pattern generally required of surround sound. Additionally, resonant panel loudspeakers tend to produce diffuse acoustic radiation, which is ideal for surround sound. These two characteristics in combination mean that the example loudspeaker unit 1 according to the present invention generally provides an extremely effective surround sound loudspeaker system. A further advantage is that operating the resonant panel loudspeaker 3 in a non-parallel orientation with respect to the wall 5 or other boundary generally increases the radiation efficiency of the panel 3.

The present invention has been described in considerable detail with reference to certain preferred versions thereof; however, other versions are possible. Therefore, the spirit and scope of the appended claims should not be limited to the description of the preferred versions contained herein.

What is claimed is:

1. A loudspeaker unit comprising, in combination, a pistonic loudspeaker and a resonant panel loudspeaker arranged such that the resonant panel loudspeaker is movable with respect to the pistonic loudspeaker.

2. A loudspeaker unit according to claim 1, in which the resonant panel loudspeaker is rotatable with respect to the pistonic loudspeaker.

3. A loudspeaker unit according to claim 1, in which the resonant panel loudspeaker is movable with respect to the pistonic loudspeaker between a first position a second position.

4. A loudspeaker unit according to claim 3, in which the resonant panel loudspeaker is movable with respect to the pistonic loudspeaker between the first position in which the resonant panel loudspeaker at least partially covers the pistonic loudspeaker, and the second position in which the pistonic loudspeaker is substantially uncovered from the resonant panel loudspeaker.

5. A loudspeaker unit according to claim 4, in which, in the first position the resonant panel loudspeaker substantially entirely covers the pistonic loudspeaker.

6. A loudspeaker unit according to claim 4, in which, when the resonant panel loudspeaker is in its second position the pistonic loudspeaker is substantially entirely uncovered from the resonant panel loudspeaker.

7. A loudspeaker unit according to claim 4, wherein:
in the first position the resonant panel loudspeaker substantially entirely covers the pistonic loudspeaker; and
when the resonant panel loudspeaker is in the second position the pistonic loudspeaker is substantially entirely uncovered from the resonant panel loudspeaker.

8. A loudspeaker unit according to claim 4, wherein the pistonic loudspeaker includes a pistonically driven diaphragm, wherein said covering or uncovering of the pistonic loudspeaker comprises covering or uncovering of the pistonically driven diaphragm.

9. A loudspeaker unit according to claim 5, wherein the pistonic loudspeaker includes a pistonically driven diaphragm, wherein said covering or uncovering of the pistonic loudspeaker comprises covering or uncovering of the pistonically driven diaphragm.

10. A loudspeaker unit according to claim 6, wherein the pistonic loudspeaker includes a pistonically driven diaphragm, wherein said covering or uncovering of the pistonic loudspeaker comprises covering or uncovering of the pistonically driven diaphragm.

11. A loudspeaker unit according to claim 7, wherein the pistonic loudspeaker includes a pistonically driven diaphragm, wherein said covering or uncovering of the pistonic loudspeaker comprises covering or uncovering of the pistonically driven diaphragm.

12. A loudspeaker unit according to claim 8, in which, when the resonant panel loudspeaker is in its second position, the resonant panel loudspeaker is oriented substantially parallel to an axis along which the diaphragm of the pistonic loudspeaker is pistonically driven.

13. A loudspeaker unit according to claim 4, in which the first position of the resonant panel loudspeaker is a non-operational position, and the second position of the resonant panel loudspeaker is an operational position in which the resonant panel loudspeaker is able to emit acoustic radiation.

14. A loudspeaker unit according to claim 5, in which the first position of the resonant panel loudspeaker is a non-operational position, and the second position of the resonant panel loudspeaker is an operational position in which the resonant panel loudspeaker is able to emit acoustic radiation.

15. A loudspeaker unit according to claim 6, in which the first position of the resonant panel loudspeaker is a non-operational position, and the second position of the resonant panel loudspeaker is an operational position in which the resonant panel loudspeaker is able to emit acoustic radiation.

16. A loudspeaker unit according to claim 8, in which the first position of the resonant panel loudspeaker is a non-operational position, and the second position of the resonant panel loudspeaker is an operational position in which the resonant panel loudspeaker is able to emit acoustic radiation.

17. A loudspeaker unit according to claim 12, in which the first position of the resonant panel loudspeaker is a non-operational position, and the second position of the resonant panel loudspeaker is an operational position in which the resonant panel loudspeaker is able to emit acoustic radiation.

18. A loudspeaker unit according to claim 1, in which the pistonic loudspeaker is a low frequency loudspeaker.

19. A loudspeaker unit according to claim 2, in which the pistonic loudspeaker is a low frequency loudspeaker.

20. A loudspeaker unit according to claim 4, in which the pistonic loudspeaker is a low frequency loudspeaker.

21. A loudspeaker unit according to claim 8, in which the pistonic loudspeaker is a low frequency loudspeaker.

22. A loudspeaker unit according to claim 13, in which the pistonic loudspeaker is a low frequency loudspeaker.

23. A loudspeaker unit comprising:
a pistonic loudspeaker;
a resonant panel loudspeaker arranged such that the resonant panel loudspeaker is movable with respect to the pistonic loudspeaker; and
a support to which the resonant panel loudspeaker is movably attached.

24. A loudspeaker unit according claim 23, further comprising a motor by means of which the resonant panel loudspeaker is movable with respect to the pistonic loudspeaker.

25. A loudspeaker unit according to claim 24, in which the resonant panel loudspeaker is movable with respect to the pistonic loudspeaker between a first position in which the resonant panel loudspeaker at least partially covers the pistonic loudspeaker, and a second position in which the pistonic loudspeaker is substantially uncovered from the resonant panel loudspeaker.

26. A loudspeaker unit according to claim 24, in which the motor is an electric motor.

27. A loudspeaker unit according to claim 24, further comprising a remote control system arranged to control the movement of the resonant panel loudspeaker.

28. A loudspeaker unit according to claim 24 in which the resonant panel loudspeaker is rotatable with respect to the support.

29. A loudspeaker unit according to claim 24, in which the resonant panel loudspeaker comprises a resonant panel and one or more exciters arranged to excite the panel.

30. A loudspeaker unit according to claim 29, in which the resonant panel comprises two opposite major surfaces, and the resonant panel loudspeaker is arranged to emit acoustic radiation from both opposite major surfaces of the panel simultaneously.

31. A loudspeaker unit according to claim 30, in which the resonant panel is substantially planar.

32. A loudspeaker unit according to claim 31, wherein the resonant panel loudspeaker is movable with respect to the pistonic loudspeaker between a first position in which the resonant panel loudspeaker at least partially covers the pistonic loudspeaker, and a second position in which the pistonic loudspeaker is substantially uncovered from the resonant panel loudspeaker.

33. A method of operating a loudspeaker unit comprising a pistonic loudspeaker and a resonant panel loudspeaker arranged such that the resonant panel loudspeaker is movable with respect to the pistonic loudspeaker, the method including the steps of:
moving the resonant panel loudspeaker between a non-operational first position and an operational second position in which the resonant panel loudspeaker is able to emit acoustic radiation.
